(19) United States
(12) Patent Application Publication
(10) Pub. No.: US 2021/0056854 A1
(43) Pub. Date: Feb. 25, 2021

(54) HIERARCHICAL AI ASSISTED SAFE AND EFFICIENT PLATOONING

(71) Applicant: Toyota Motor Engineering & Manufacturing North America, Inc., Erlanger, KY (US)

(72) Inventors: Seyhan Ucar, Mountain View, CA (US); Baik Hoh, Mountain View, CA (US); Kentaro Oguchi, Mountain View, CA (US)

(21) Appl. No.: 16/549,521

(22) Filed: Aug. 23, 2019

(51) Int. Cl. G08G 1/00; G05D 1/02; G08G 1/01; G06F 17/50; G05D 1/00; G06N 20/00; H04W 4/44; H04W 4/46

(52) U.S. Cl. CPC G08G 1/22; G05D 1/0295; G08G 1/0125; H04W 4/46; G05D 1/0088; G06N 20/00; H04W 4/44; G06F 17/5009

(57) ABSTRACT

The disclosure includes embodiments for managing a vehicle platoon. In some embodiments, a method includes receiving a request to execute a vehicle platooning maneuver from a vehicle operating in a roadway environment. The method includes executing a simulation. The method includes determining an area in the roadway environment where the vehicle platooning maneuver is executed based on the simulation. The method includes instructing the vehicle to execute the vehicle platooning maneuver at the area.

### BACKGROUND

The specification relates to managing a vehicle platoon.

A vehicle platoon may include a group of vehicles that travel close to one another. A vehicle that leads the group of vehicles may be referred to as a leader vehicle and remaining participating vehicles that follow the leader vehicle may be referred to as following vehicles. The vehicles in the vehicle platoon may adopt Cooperative Adaptive Cruise Control (CACC) systems to cooperate with one another. Vehicle platooning may be used to enhance autonomous behavior for the group of vehicles, where the vehicles may communicate with one another using Vehicle-to-Everything (V2X) communications.

### SUMMARY

One general aspect of embodiments described herein includes a computer program product including a non-transitory memory of a computer system storing computer-executable code that, when executed by a processor, causes the processor to: receive a request to execute a vehicle platooning maneuver from a vehicle operating in a roadway environment; execute a simulation that is seeded with hierarchical artificial intelligence (AI) data; determine an area in the roadway environment where the vehicle platooning maneuver is executed based on the simulation; and instruct the vehicle to execute the vehicle platooning maneuver at the area. Other embodiments of this aspect include corresponding computer systems, apparatus, and computer programs recorded on one or more computer storage devices, each configured to perform the actions of the methods.

Implementations may include one or more of the following features. The computer program product where the hierarchical AI data describes one or more of the following: real-life traffic information; real-time traffic information; and predicted future traffic information. The computer program product where the computer-executable code, when executed by the processor, causes the processor further to execute one or more of the following steps: determine whether to reconfigure a vehicle platoon after the vehicle platooning maneuver is executed so that one or more goals are satisfied. The computer program product where the computer-executable code, when executed by the processor, causes the processor further to execute one or more of the following steps: determine how to reconfigure a vehicle platoon after the vehicle platooning maneuver is executed so that one or more goals are satisfied. Implementations of the described techniques may include hardware, a method or process, or computer software on a computer-accessible medium.

One general aspect includes a method, including: receiving a request to execute a vehicle platooning maneuver from a vehicle operating in a roadway environment; executing a simulation; determining an area in the roadway environment where the vehicle platooning maneuver is executed based on the simulation; and instructing the vehicle to execute the vehicle platooning maneuver at the area. Other embodiments of this aspect include corresponding computer systems, apparatus, and computer programs recorded on one or more computer storage devices, each configured to perform the actions of the methods.

Implementations may include one or more of the following features. The method where the vehicle is an autonomous vehicle. The method where the simulation is a digital twin simulation. The method where the simulation is seeded with hierarchical artificial intelligence data that describes one or more of the following: real-life traffic information; real-time traffic information; and predicted future traffic information. The method where the method is executed by at least one processor-based computing device selected from the following set of processor-based computing devices: an onboard unit of a leader vehicle of a vehicle platoon; and a server. The method further including one or more of the following steps: determining whether to reconfigure a vehicle platoon after the vehicle platooning maneuver is executed so that one or more goals are satisfied. The method further including one or more of the following steps: determining how to reconfigure a vehicle platoon after the vehicle platooning maneuver is executed so that one or more goals are satisfied. The method where executing the simulation includes: determining a set of candidate areas in the roadway environment for executing the vehicle platooning maneuver; executing the simulation to implement the vehicle platooning maneuver at the set of candidate areas respectively; and selecting, from the set of candidate areas, a candidate area where an execution of the vehicle platooning maneuver in the simulation satisfies one or more platooning requirements, where the candidate area is determined as the area in the roadway environment where the vehicle platooning maneuver is executed. Implementations of the described techniques may include hardware, a method or process, or computer software on a computer-accessible medium.

One general aspect includes a system including a computer system including a non-transitory memory storing computer code which, when executed by the computer system, causes the computer system to: receive a request to execute a vehicle platooning maneuver from a vehicle operating in a roadway environment; execute a simulation; determine an area in the roadway environment where the vehicle platooning maneuver is executed based on the simulation; and instruct the vehicle to execute the vehicle platooning maneuver at the area. Other embodiments of this aspect include corresponding computer systems, apparatus, and computer programs recorded on one or more computer storage devices, each configured to perform the actions of the methods.

Implementations may include one or more of the following features. The system where the vehicle is an autonomous vehicle. The system where the simulation is a digital twin simulation. The system where the simulation is seeded with hierarchical artificial intelligence data that describes one or more of the following: real-life traffic information; real-time traffic information; and predicted future traffic information. The system where the computer system is included in at least one processor-based computing device selected from the following set of processor-based computing devices: an onboard unit of a leader vehicle of a vehicle platoon; and a server. The system where the computer code, when executed by the computer system, causes the computer system further to one or more of the following steps: determine whether to reconfigure a vehicle platoon after the vehicle platooning maneuver is executed so that one or more goals are satisfied. The system where the computer code, when executed by the computer system, causes the computer system further to one or more of the following steps: determine how to reconfigure a vehicle platoon after the vehicle platooning maneuver is executed so that one or more goals are satisfied. The system where the computer code, when executed by the computer system, causes the computer system to execute the simulation at least by: determining a set of candidate areas in the roadway environment for executing the vehicle platooning maneuver; executing the simulation to implement the vehicle platooning maneuver at the set of candidate areas respectively; and selecting, from the set of candidate areas, a candidate area where an execution of the vehicle platooning maneuver in the simulation satisfies one or more platooning requirements, where the candidate area is determined as the area in the roadway environment where the vehicle platooning maneuver is executed. Implementations of the described techniques may include hardware, a method or process, or computer software on a computer-accessible medium.

### BRIEF DESCRIPTION OF THE DRAWINGS

The disclosure is illustrated by way of example, and not by way of limitation in the figures of the accompanying drawings in which like reference numerals are used to refer to similar elements.

FIG. 1 is a block diagram illustrating an operating environment for an AI platoon system and an AI client according to some embodiments.

FIG. 2 is a block diagram illustrating an example computer system including the AI platoon system according to some embodiments.

FIG. 3 depicts a method for managing a vehicle platoon according to some embodiments.

FIGS. 4A-4B depict another method for managing a vehicle platoon according to some embodiments.

FIG. 5A is a block diagram illustrating an architecture for the AI platoon system and the AI client according to some embodiments.

FIG. 5B is a graphical representation illustrating an example approach for learning hierarchical AI data according to some embodiments.

FIGS. 6A-6B are graphical representations illustrating an example of managing a vehicle platoon with a vehicle platooning maneuver according to some embodiments.

FIGS. 7A-7B are graphical representations illustrating another example of managing a vehicle platoon with a vehicle platooning maneuver according to some embodiments.

FIGS. 8A-8D are graphical representations illustrating an example of managing a vehicle platoon with a platoon reconfiguration maneuver according to some embodiments.

### DETAILED DESCRIPTION

There may be various ways to form a vehicle platoon in a roadway environment. For example, a vehicle may initially search for a vehicle platoon so that it can join the vehicle platoon when entering a freeway. If there is an existing vehicle platoon, the vehicle may participate in the existing vehicle platoon. However, if there is no existing vehicle platoon, a new vehicle platoon may be formed to include the vehicle as a member vehicle of the vehicle platoon.

Specifically, the vehicle may search for and join a vehicle platoon based on one or more parameters. For example, the vehicle may join a vehicle platoon based on a cost-based method to achieve a minimum number of platooning maneuvers. In another example, the vehicle may join a vehicle platoon based on a route-based method so that vehicles with a same destination may join the same vehicle platoon. In yet another example, the vehicle may join a vehicle platoon such that similarity between the vehicle and the vehicle platoon (e.g., in terms of speeds, current positions, etc.) is maximized.

Application of the vehicle platooning can be beneficial in various aspects. For example, a traffic throughput can be improved with a formation of a vehicle platoon within which member vehicles can cooperate with one another to plan ahead and drive closer than non-platooned vehicles. The member vehicles in the vehicle platoon may have a smaller speed variation and a smaller distance variation than the non-platooned vehicles. In another example, safety of the member vehicles can be enhanced through a faster response to events when compared to the non-platooned vehicles. In yet another example, fuel consumption and emissions can be reduced due to a stable movement of the vehicle platoon on the roadway (e.g., due to a decreased variation on acceleration or deceleration of the member vehicles).

Although many efforts have been devoted to implementing the vehicle platooning, it is still not easy to ensure safety and efficiency of a vehicle platoon. For example, various vehicle platooning maneuvers may need to be performed on a vehicle platoon under different road conditions and different traffic conditions. Existing solutions focus on a design of platoon management protocols with an assumption that the vehicle platoon has enough spaces and safe conditions for the execution of the vehicle platooning maneuvers. The existing solutions fail to consider optimal locations where the vehicle platooning maneuvers can be executed safely and successfully.

Moreover, an execution of a vehicle platooning maneuver can change a configuration of the vehicle platoon (e.g., vehicle ordering), where the vehicle platoon may become inefficient due to a change of the vehicle ordering. For example, after the execution of the vehicle platooning maneuver, a large truck may be positioned at the rear of the vehicle platoon, which may result in a reduction of fuel efficiency in the vehicle platoon. The existing solutions also fail to consider a dynamic update of the configuration of the vehicle platoon to maximize efficiency after the vehicle platooning maneuver is performed.

Described herein are embodiments of an AI platoon system installed in a server (or, a leader vehicle) and an AI client installed in a vehicle. The AI platoon system and the AI client may cooperate with one another to manage a vehicle platoon so that a vehicle platooning maneuver can be executed safely and successfully on the vehicle platoon. The AI platoon system and the AI client may also cooperate with one another to reconfigure the vehicle platoon using a platoon reconfiguration maneuver so that an efficiency of the vehicle platoon can be maximized.

Specifically, the AI platoon system hierarchically leverages large scale and fragmented vehicle data (e.g., sensor data) in real time or near real time to generate hierarchical AI data. The AI platoon system incorporates the hierarchical AI data into a determination of whether to perform a vehicle platooning maneuver on the vehicle platoon or not and where (or when) to perform the vehicle platooning maneuver.

For example, the AI platoon system computes a set of candidate locations for executing the vehicle platooning maneuver. The AI platoon system simulates the execution of the maneuver on the set of candidate locations before the maneuver is actually executed by including actual traffic dynamics, predicted traffic dynamics or a combination thereof into the simulation. The AI platoon system selects, from the set of candidate locations, a candidate location where the execution of the vehicle platooning maneuver in the simulation is safe and successful. The selected candidate location is a target location where the vehicle platooning maneuver is actually executed in the roadway. The AI platoon system may reroute the vehicle platoon to the target location and the AI client may reroute the vehicle to the target location, so that the vehicle platooning maneuver may be executed at the target location in the roadway.

After a successful execution of the vehicle platooning maneuver at the target location, the AI platoon system may measure an efficiency of a configuration of the vehicle platoon. The AI platoon system may perform a platoon reconfiguration maneuver on the vehicle platoon to achieve a maximum efficiency.

Example improvements and advantages provided by the AI platoon system and the AI client described herein are provided here. For example, based on hierarchical AI data, the AI platoon system and the AI client may cooperate with one another to determine a target location so that a vehicle platooning maneuver can be executed safely and successfully at the target location. In another example, the AI platoon system and the AI client may cooperate with one another to reconfigure the vehicle platoon to improve an efficiency of the vehicle platoon. Other example advantages are also possible.

As described herein, a vehicle platooning maneuver may include any maneuver to be executed on a vehicle platoon. Examples of a vehicle platooning maneuver include, but are not limited to, the following: an entrance maneuver (e.g., a new vehicle entering the vehicle platoon); and a leaving maneuver or an exit maneuver (e.g., a member vehicle leaving the vehicle platoon). Further examples of a vehicle platooning maneuver include: a merging maneuver (e.g., two or more vehicle platoons being merged as a new vehicle platoon); and a splitting maneuver (e.g., the vehicle platoon being split into multiple vehicle platoons), etc.

As described herein, a platoon reconfiguration maneuver may include one or more vehicle platooning maneuvers used to reconfigure a vehicle platoon. For example, the platoon reconfiguration maneuver may include one or more consecutive vehicle platooning maneuvers used to reorder vehicles in the vehicle platoon (e.g., a splitting maneuver followed by a merging maneuver). The platoon reconfiguration maneuver may reconfigure the vehicle platoon to achieve one or more goals (e.g., reordering the member vehicles to achieve a better fuel efficiency, re-electing a new leader vehicle based on available resources, etc.).

### Example Overview

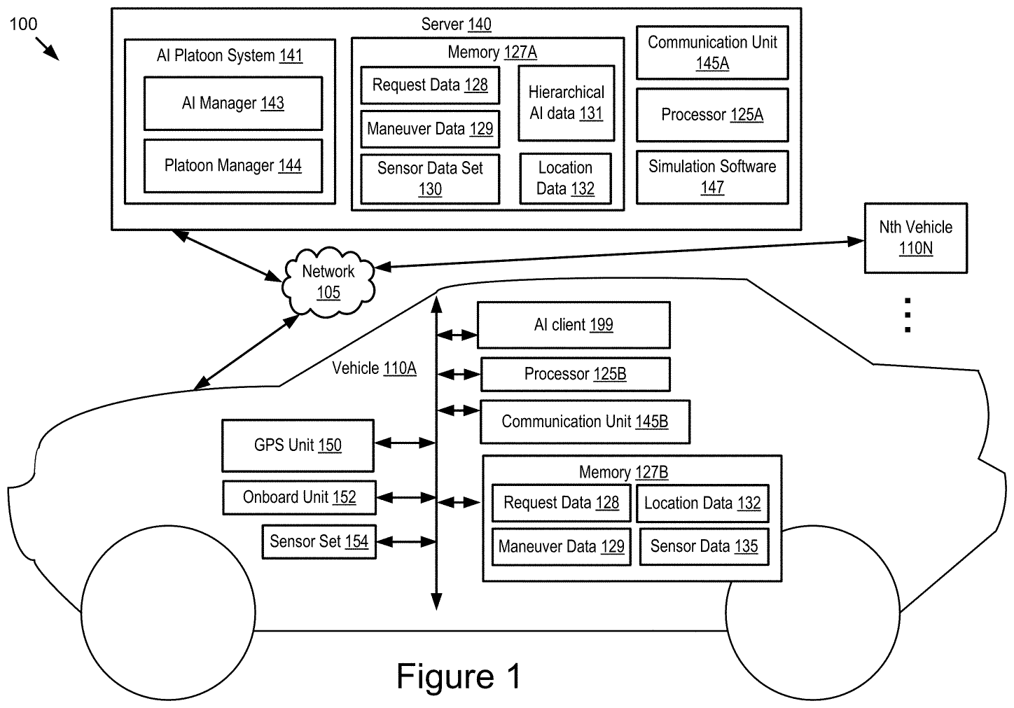

Referring to FIG. 1, depicted is an operating environment 100 for an AI platoon system 141 and an AI client 199 according to some embodiments. The operating environment 100 may include one or more of the following elements: one or more vehicles 110A, . . . , 110N (e.g., referred to as vehicle 110, individually or collectively); and a server 140. These elements of the operating environment 100 may be communicatively coupled to a network 105. In practice, the operating environment 100 may include any number of vehicles 110, servers 140 and networks 105.

The network 105 may be a conventional type, wired or wireless, and may have numerous different configurations including a star configuration, token ring configuration, or other configurations. Furthermore, the network 105 may include a local area network (LAN), a wide area network (WAN) (e.g., the Internet), or other interconnected data paths across which multiple devices and/or entities may communicate. In some embodiments, the network 105 may include a peer-to-peer network. The network 105 may also be coupled to or may include portions of a telecommunications network for sending data in a variety of different communication protocols. In some embodiments, the network 105 includes Bluetooth® communication networks or a cellular communications network for sending and receiving data including via short messaging service (SMS) and multimedia messaging service (MMS). In some embodiments, the network 105 further includes networks for hypertext transfer protocol (HTTP), direct data connection, wireless application protocol (WAP), e-mail, Dedicated Short Range Communication (DSRC), full-duplex wireless communication and mmWave. In some embodiments, the network 105 further includes networks for WiFi (infrastructure mode), WiFi (ad-hoc mode), visible light communication, TV white space communication and satellite communication. The network 105 may also include a mobile data network that may include 3G, 4G, Long Term Evolution (LTE), LTE-V2X, LTE-Device-to-Device (LTE-D2D), Voice over LTE (VoLTE), 5G-V2X or any other mobile data network. The network 105 may also include any combination of mobile data networks. Further, the network 105 may include one or more IEEE 802.11 wireless networks.

The server 140 may be any server that includes one or more processors and one or more memories. For example, the server 140 may be a cloud server, an edge server, or any other type of server. In some embodiments, the server 140 may include one or more of the following elements: a processor 125A; a memory 127A; a communication unit 145A; a simulation software 147; and the AI platoon system 141.

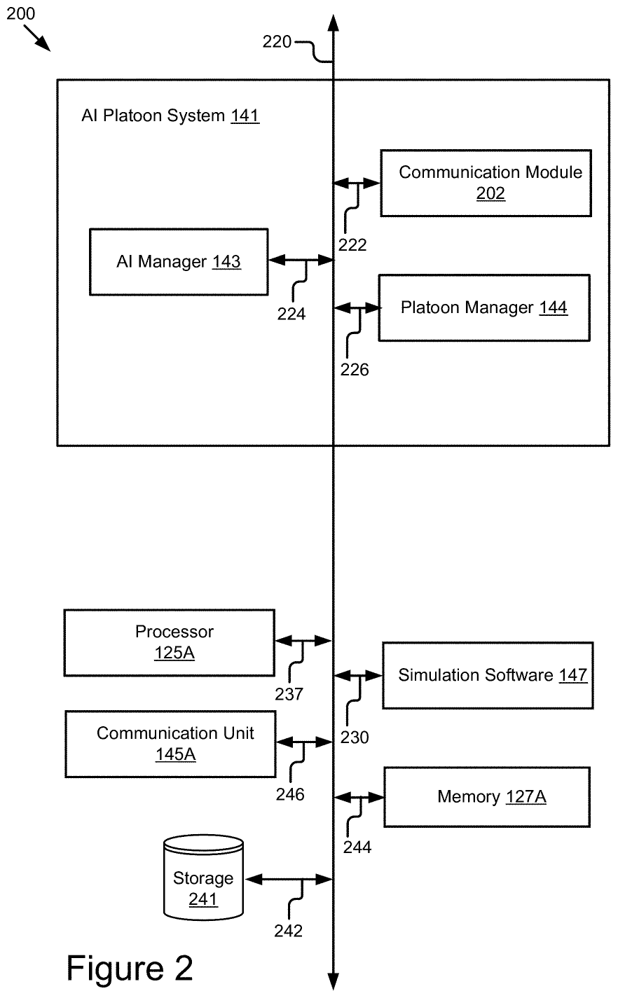

In some embodiments, the processor 125A and the memory 127A may be elements of a computer system (such as computer system 200 described below with reference to FIG. 2). The computer system may be operable to cause or control the operation of the AI platoon system 141. For example, the computer system may be operable to access and execute the data stored on the memory 127A to provide the functionality described herein for the AI platoon system 141 or its elements (see, e.g., FIG. 2).

The processor 125A includes an arithmetic logic unit, a microprocessor, a general-purpose controller, or some other processor array to perform computations and provide electronic display signals to a display device. The processor 125A processes data signals and may include various computing architectures. Example computing architectures include a complex instruction set computer (CISC) architecture, a reduced instruction set computer (RISC) architecture, or an architecture implementing a combination of instruction sets. The server 140 may include one or more processors 125A. Other processors, operating systems, sensors, displays, and physical configurations may be possible.

The memory 127A stores instructions or data that may be executed by the processor 125A. The instructions or data may include code for performing the techniques described herein. The memory 127A may be a dynamic random-access memory (DRAM) device, a static random-access memory (SRAM) device, flash memory, or some other memory device. In some embodiments, the memory 127A also includes a non-volatile memory or similar permanent storage device and media. Example permanent storage devices include a hard disk drive, a floppy disk drive, a CD-ROM device, a DVD-ROM device, a DVD-RAM device, a DVD-RW device, and a flash memory device, etc. Additional example permanent storage devices may include some other mass storage device for storing information on a more permanent basis. The server 140 may include one or more memories 127A.

The memory 127A may store one or more of the following elements: request data 128; maneuver data 129; sensor data set 130; hierarchical AI data 131; and location data 132.

The request data 128 may include digital data that describes a request to execute a vehicle platooning maneuver. In some embodiments, the request may be received from the vehicle 110. For example, the request is a request to execute an entrance maneuver received from the vehicle 110 so that the vehicle 110 can join a vehicle platoon after an execution of the entrance maneuver.

In some embodiments, the request may be received from a leader vehicle, a following vehicle or any other suitable entity. For example, the request is a request to execute a splitting maneuver received from the leader vehicle so that the vehicle platoon can be split into two new vehicle platoons after an execution of the splitting maneuver. In another example, the request is a request to execute an exit maneuver received from a following vehicle so that the following vehicle can exit from the vehicle platoon after an execution of the exit maneuver.

The maneuver data 129 may include digital data that describes a vehicle platooning maneuver to be executed. In some embodiments, the maneuver data 129 may also include digital data that describes a platoon reconfiguration maneuver to be executed on a vehicle platoon.

The sensor data set 130 may include various sensor data received from various vehicles 110, roadside units or any other infrastructure devices in a roadway environment.

The hierarchical AI data 131 may include digital data that describes one or more of the following: real-life traffic information; real-time traffic information; and predicted future traffic information. The hierarchical AI data 131 can be generated based on sensor data included in the sensor data set 130.

The location data 132 can include digital data that describes an area (e.g., a geographic location, a geographic region, etc.) in the roadway environment where a vehicle platooning maneuver is executed. In some embodiments, the area where the vehicle platooning maneuver is executed can be referred to as a “target location” or a “target area” for convenience of discussion.

The communication unit 145A transmits and receives data to and from the network 105 or to another communication channel. In some embodiments, the communication unit 145A may include a DSRC transceiver, a DSRC receiver and other hardware or software necessary to make the server 140 a DSRC-enabled device. For example, the communication unit 145A includes a DSRC antenna configured to broadcast DSRC messages via the network. The DSRC antenna may also transmit BSM messages at a fixed or variable interval (e.g., every 0.1 seconds, at a time interval corresponding to a frequency range from 1.6 Hz to 10 Hz, etc.) that is user configurable.

In some embodiments, the communication unit 145A includes a port for direct physical connection to the network 105 or to another communication channel. For example, the communication unit 145A includes a USB, SD, CAT-5, or similar port for wired communication with the network 105. In some embodiments, the communication unit 145A includes a wireless transceiver for exchanging data with the network 105 or other communication channels using one or more wireless communication methods. Example wireless communication methods may include one or more of the following: IEEE 802.11; and IEEE 802.16, BLUETOOTH®. Example wireless communication methods may further include EN ISO 14906:2004 Electronic Fee Collection—Application interface EN 11253:2004 DSRC—Physical layer using microwave at 5.8 GHz (review). Example wireless communication methods may further include EN 12795:2002 DSRC—DSRC Data link layer: Medium Access and Logical Link Control (review). Example wireless communication methods may further include EN 12834:2002 DSRC—Application layer (review) and EN 13372:2004 DSRC—DSRC profiles for RTTT applications (review). Example wireless communication methods may further include the communication method described in U.S. patent application Ser. No. 14/471,387 filed on Aug. 28, 2014 and entitled “Full-Duplex Coordination System”; or another suitable wireless communication method.

In some embodiments, the communication unit 145A includes a cellular communications transceiver for sending and receiving data over a cellular communications network. For example, the data may be sent or received via short messaging service (SMS), multimedia messaging service (MMS), hypertext transfer protocol (HTTP), direct data connection, WAP, e-mail, or another suitable type of electronic communication. In some embodiments, the communication unit 145A includes a wired port and a wireless transceiver. The communication unit 145A also provides other conventional connections to the network 105 for distribution of files or media objects using standard network protocols including TCP/IP, HTTP, HTTPS, and SMTP, millimeter wave, DSRC, etc.

The communication unit 145A may include a V2X radio. The V2X radio may include a hardware element including a DSRC transmitter which is operable to transmit DSRC messages on the 5.9 GHz band. The 5.9 GHz band is reserved for DSRC messages. The hardware element may also include a DSRC receiver which is operable to receive DSRC messages on the 5.9 GHz band.

The simulation software 147 may be any simulation software that is capable of simulating an execution of a vehicle platooning maneuver, a platoon reconfiguration maneuver, or a combination thereof. For example, the simulation software 147 may be a simulation software that is capable of conducting a digital twin simulation.

A digital twin can be a simulated version of a specific real-world vehicle that exists in a simulation. A structure, condition, behavior, and responses of the digital twin are similar to a structure, condition, behavior, and responses of the specific real-world vehicle that the digital twin represents in the simulation. The digital environment included in the simulation may be similar to the real-world operating environment of the real-world vehicle. The simulation software 147 may include code and routines that are operable to execute simulations based on digital twins of real-world vehicles in the roadway environment.

In some embodiments, the simulation software 147 may be integrated with the AI platoon system 141. In some other embodiments, the simulation software 147 may be a standalone software that the AI platoon system 141 can access to execute simulations for a vehicle platooning maneuver or a platoon reconfiguration maneuver.

The AI platoon system 141 includes software that is operable to manage a vehicle platoon. In some embodiments, the AI platoon system 141 may be implemented using hardware including a field-programmable gate array (“FPGA”) or an application-specific integrated circuit (“ASIC”). In some other embodiments, the AI platoon system 141 may be implemented using a combination of hardware and software. The AI platoon system 141 may be stored in a combination of the devices (e.g., servers or other devices), or in one of the devices.

Although the AI platoon system 141 is installed in the server 140 in FIG. 1, the AI platoon system 141 may be installed in a member vehicle of the vehicle platoon such as a leader vehicle of the vehicle platoon.

In some embodiments, the AI platoon system 141 may include one or more of the following elements: a hierarchical AI manager 143 (referred to as “AI manager 143” for convenience); and a platoon manager 144. The AI platoon system 141 including the AI manager 143 and the platoon manager 144 is described below in more detail with reference to FIGS. 2-8D.

The vehicle 110 may be any type of vehicle. For example, the vehicle 110 may include one of the following types of vehicles: a car; a truck; a sports utility vehicle; a bus; a semi-truck; a drone; or any other roadway-based conveyance. The vehicle 110 may be a connected vehicle that includes a communication unit and is capable of communicating with other endpoints connected to the network 105.

In some embodiments, the vehicle 110 is a DSRC-enabled vehicle which includes a DSRC radio and a DSRC-compliant Global Positioning System (GPS) unit. The vehicle 110 may also include other V2X radios besides a DSRC radio. DSRC is not a requirement of embodiments described herein, and any form of V2X communications is also feasible. Further examples of V2X communications include one or more of the following: LTE; millimeter wave (mmWave) communication; 3G; 4G; 5G; LTE-V2X; 5G-V2X; LTE-Vehicle-to-Vehicle (LTE-V2V); LTE-D2D; or VoLTE; etc. In some examples, the V2X communications can include V2V communications, Vehicle-to-Infrastructure (V2I) communications, Vehicle-to-Network (V2N) communications or any combination thereof.

The vehicle 110 may include one or more of the following elements: a processor 125B; a memory 127B; a communication unit 145B; a GPS unit 150; an onboard unit 152; a sensor set 154; and the hierarchical AI client 199 (referred to as “AI client 199” for convenience). These elements of the vehicle 110 may be communicatively coupled to one another via a bus.

The processor 125B, the memory 127B and the communication unit 145B may provide functionality similar to that of the processor 125A, the memory 127A and the communication unit 145A, respectively. Similar description will not be repeated here.

The memory 127B may store one or more of the following elements: the request data 128; the maneuver data 129; the location data 132; and sensor data 135. The request data 128, the maneuver data 129 and the location data 132 are described above, and those descriptions will not be repeated here.

The sensor data 135 may include digital data describing one or more sensor measurements of the sensor set 154. For example, the sensor data 135 may include vehicle data describing the vehicle 110 (e.g., GPS location data, speed data, heading data, etc.) and other sensor data describing a roadway environment (e.g., camera data depicting a roadway, etc.).

The sensor set 154 includes one or more sensors that are operable to measure a roadway environment outside of the vehicle 110. For example, the sensor set 154 may include one or more sensors that record one or more physical characteristics of the roadway environment that is proximate to the vehicle 110. The memory 127B may store the sensor data 135 that describes the one or more physical characteristics recorded by the sensor set 154.

The sensor set 154 may also include various sensors that record an environment internal to a cabin of the vehicle 110. For example, the sensor set 154 includes onboard sensors which monitor the environment of the vehicle 110 whether internally or externally. In a further example, the sensor set 154 includes cameras, LIDAR, radars, infrared sensors, and sensors that observe the behavior of the driver such as internal cameras, biometric sensors, etc.

In some embodiments, the sensor set 154 may include one or more of the following vehicle sensors: a camera; a LIDAR sensor; a radar sensor; a laser altimeter; an infrared detector; a motion detector; a thermostat; and a sound detector. The sensor set 154 may also include one or more of the following sensors: a carbon monoxide sensor; a carbon dioxide sensor; an oxygen sensor; a mass air flow sensor; and an engine coolant temperature sensor. The sensor set 154 may also include one or more of the following sensors: a throttle position sensor; a crank shaft position sensor; an automobile engine sensor; a valve timer; an air-fuel ratio meter; and a blind spot meter. The sensor set 154 may also include one or more of the following sensors: a curb feeler; a defect detector; a Hall effect sensor, a manifold absolute pressure sensor; a parking sensor; a radar gun; a speedometer; and a speed sensor. The sensor set 154 may also include one or more of the following sensors: a tire-pressure monitoring sensor; a torque sensor; a transmission fluid temperature sensor; and a turbine speed sensor (TSS); a variable reluctance sensor; and a vehicle speed sensor (VSS). The sensor set 154 may also include one or more of the following sensors: a water sensor; a wheel speed sensor; and any other type of automotive sensor.

In some embodiments, the GPS unit 150 is a conventional GPS unit of the vehicle 110. For example, the GPS unit 150 may include hardware that wirelessly communicates with a GPS satellite to retrieve data that describes a geographic location of the vehicle 110. In some embodiments, the GPS unit 150 is a DSRC-compliant GPS unit of the vehicle 110. The DSRC-compliant GPS unit is operable to provide GPS data describing the geographic location of the vehicle 110 with lane-level accuracy.

The onboard unit 152 can include one or more processors and one or more memories. For example, the onboard unit 152 may be an electronic control Unit (ECU). The onboard unit 152 may control an operation of the sensor set 154 and the AI client 199 of the vehicle 110. In some embodiments, the AI client 199 is installed in the onboard unit 152.

The AI client 199 includes software that is operable to manage the vehicle 110 for a completion of a vehicle platooning maneuver. In some embodiments, the AI client 199 may be implemented using hardware including an FPGA or an ASIC. In some other embodiments, the AI client 199 may be implemented using a combination of hardware and software. The AI client 199 may be stored in a combination of the devices (e.g., servers or other devices), or in one of the devices.

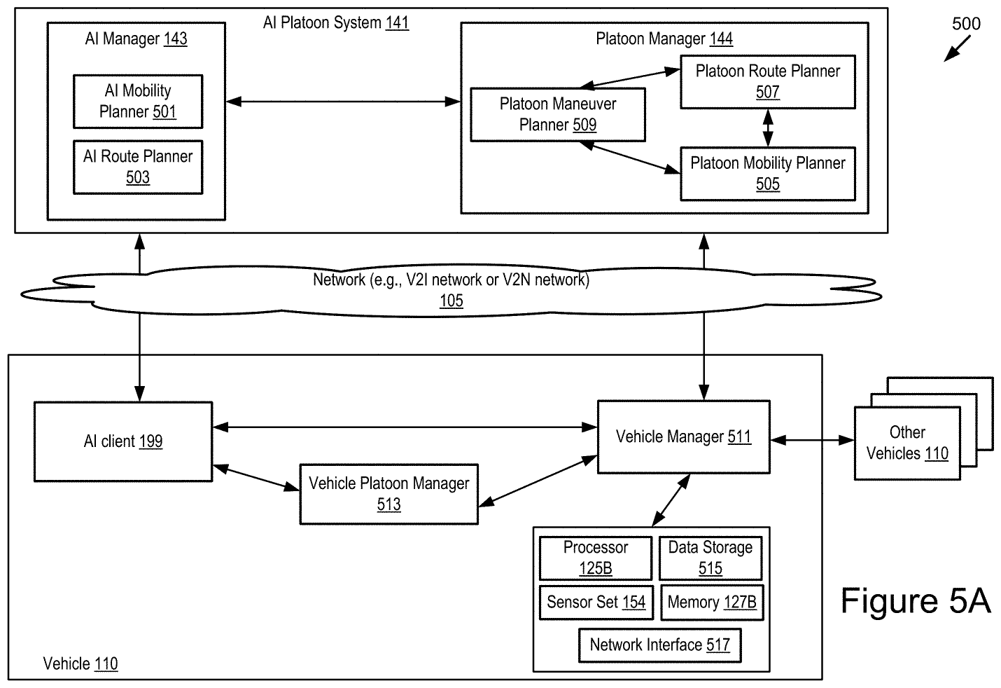

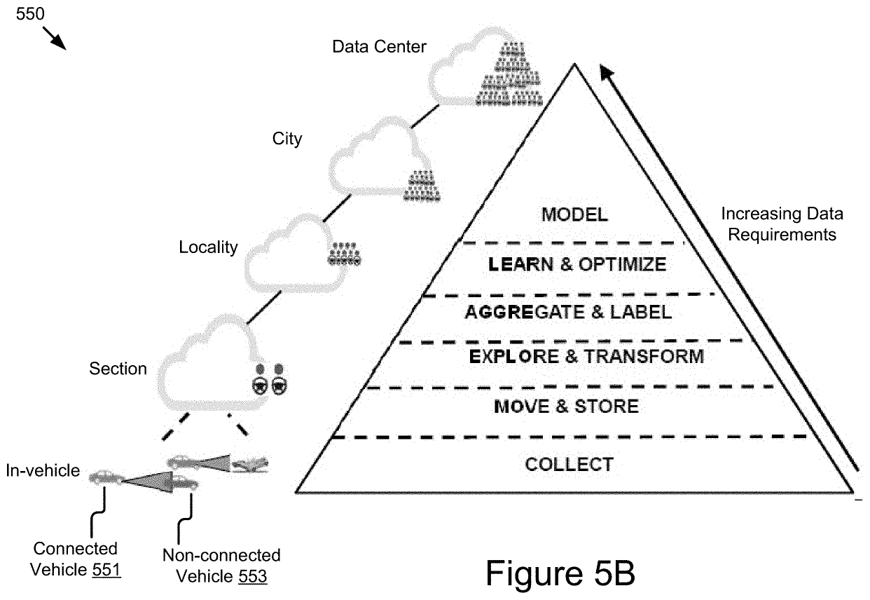

The AI client 199 is described below in more detail with reference to FIGS. 5A and 6A-8D.

An example overview of the AI platoon system 141 and the AI client 199 is illustrated here, followed by a specific example that illustrates a cooperation process between the AI platoon system 141 and the AI client 199. The AI platoon system 141 and the AI client 199 described herein are applicable for vehicle platoons that include traditional vehicles, autonomous vehicles, or a combination thereof.

In this example overview, assume that an operating environment includes a plurality of connected vehicles. Optionally, the operating environment includes one or more non-connected vehicles. The connected vehicles include a set of onboard sensors such as GPS, LIDAR, radar, cameras, sonar, etc. These vehicles also include onboard computing hardware such as processors and hard drives. The vehicles may use V2X communications to form vehicle platoons. A vehicle executes a vehicle platooning maneuver (e.g., an entrance maneuver) when it wants to join a vehicle platoon.

In some embodiments, the AI platoon system 141 is operable to use simulations to execute the following operations: (1) determining a geographic area on a roadway to execute the vehicle platooning maneuver based on certain predetermined platooning requirements; (2) executing the vehicle platooning maneuver at the geographic area; (3) determining whether the vehicle platoon needs to be reconfigured; (4) determining how this vehicle platoon may be reconfigured in order to meet certain predetermined goals; and (5) reconfiguring the vehicle platoon.

In some embodiments, the above operations (1), (3) and (4) are executed using hierarchical AI techniques. For example, the simulations at the operations (1), (3) and (4) are seeded with hierarchical AI data.

In some embodiments, the simulations are digital twin simulations. The operations (1), (3) and (4) may be executed using digital twin simulations which are seeded with hierarchical AI data. The hierarchical AI data includes, for example, real-time traffic information and predicted future traffic information.

In some embodiments, the vehicle platoon is a micro vehicular cloud.

In the specific example that illustrates a cooperation process between the AI platoon system 141 and the AI client 199, assume that the vehicles each include an instance of the AI client 199. The vehicles use V2X communications to communicate with the server 140 that includes the AI platoon system 141.

The AI client 199 wirelessly communicates sensor data describing itself and other traffic participants it observes to the AI platoon system 141. All the other vehicles within a particular region (e.g., a city) do the same. The AI platoon system 141 analyzes the sensor data to extract real-time traffic information for the region and predict future traffic information for the region. The real-time traffic information and predicted future traffic information are described by the hierarchical AI data. Generation of this real-time traffic information and predicted future traffic information is background technology which is utilized by the AI platoon system 141 to improve vehicle platooning maneuvers and platoon reconfiguration maneuvers.

In this specific example, a vehicle platoon includes a set of vehicles, and the set of vehicles each include an instance of the AI client 199. The AI client 199 causes the onboard sensors of the vehicles to collect sensor data and upload this sensor data to the server 140. The server 140 receives the sensor data from a large number of vehicles within the region over a period of time so that the AI platoon system 141 is able to generate the hierarchical AI data.

The AI platoon system 141 uses the simulation software 147 to execute simulations which are used to complete one or more of the operations (1), (3) and (4) described above. The simulation software 147 is seeded with the hierarchical AI data so that it is able to execute these simulations with the benefit of the real-time traffic information and predicted future traffic information which is described by the hierarchical AI data.

The AI platoon system 141 receives a request to execute a vehicle platooning maneuver from a particular vehicle which is located in a particular sub-region which is managed by the AI platoon system 141. The AI platoon system 141 then executes the operations (1)-(5) based on the request.

From the above discussion for FIG. 1 as well as additional description provided below for FIGS. 2-8D, it can be seen that operations of the AI platoon system 141 and the AI client 199 are different from existing technologies. For example, the AI platoon system 141 determines where in a geographic sub-region that a vehicle platooning maneuver can be executed. In another example, the AI platoon system 141 determines where to execute the vehicle platooning maneuver based on any of the following: (1) simulations; (2) digital twin simulations; or (3) simulations which are seeded with hierarchical AI data. In yet another example, the AI platoon system 141 further determines whether to reconfigure a vehicle platoon after its formation and determines how to reconfigure the vehicle platoon. In still yet another example, the AI platoon system 141 determines whether or how to reconfigure a vehicle platoon based on any of the following: (1) simulations; (2) digital twin simulations; or (3) simulations which are seeded with hierarchical AI data. However, the existing technologies fail to perform any of these operations.

### Example Computer System

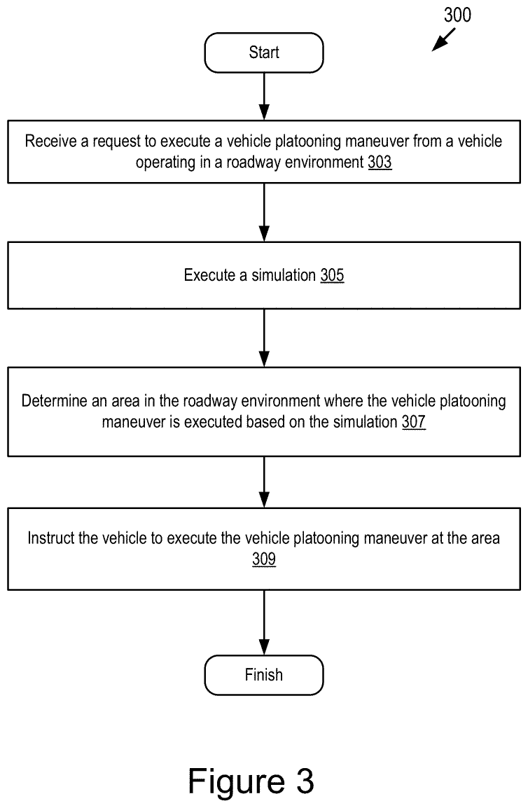

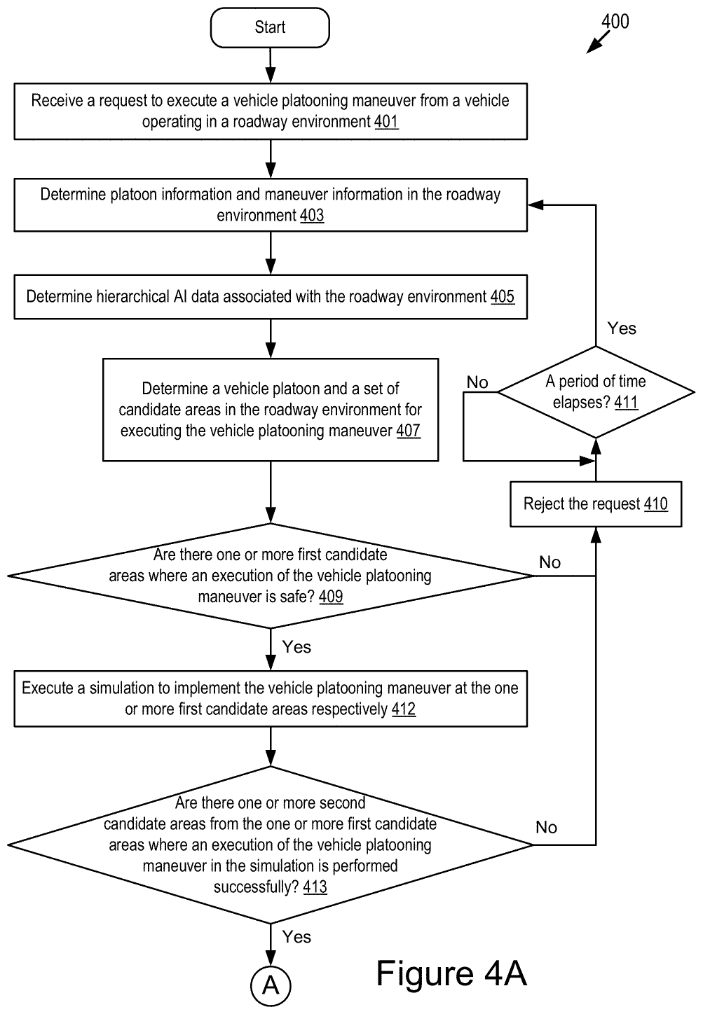

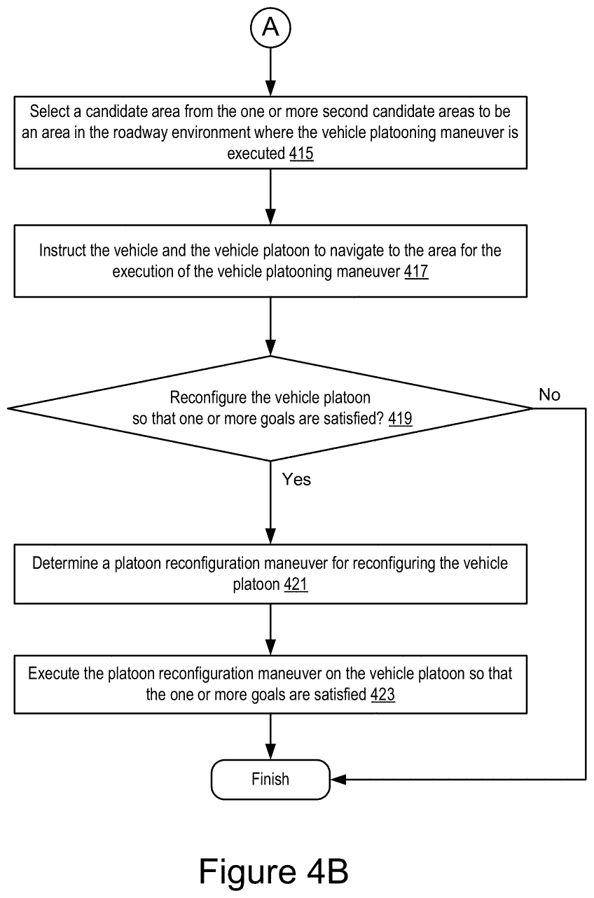

Referring now to FIG. 2, depicted is a block diagram illustrating an example computer system 200 including the AI platoon system 141 according to some embodiments. In some embodiments, the computer system 200 may include a special-purpose computer system that is programmed to perform one or more steps of methods 300 and 400 described below with reference to FIGS. 3-4B.

In some embodiments, the computer system 200 may be an element of the server 140. In some other embodiments, the computer system 200 may be an element of a member vehicle in a vehicle platoon (e.g., a leader vehicle or a following vehicle in the vehicle platoon).

The computer system 200 may include one or more of the following elements according to some examples: the AI platoon system 141; the processor 125A; and the communication unit 145A. The computer system 200 may further include one or more of the following elements: the simulation software 147; the memory 127A; and a storage 241. The components of the computer system 200 are communicatively coupled by a bus 220.

In the illustrated embodiment, the processor 125A is communicatively coupled to the bus 220 via a signal line 237. The communication unit 145A is communicatively coupled to the bus 220 via a signal line 246. The storage 241 is communicatively coupled to the bus 220 via a signal line 242. The simulation software 147 is communicatively coupled to the bus 220 via a signal line 230. The memory 127A is communicatively coupled to the bus 220 via a signal line 244.

The following elements are described above with reference to FIG. 1: the processor 125A; the communication unit 145A; the simulation software 147; and the memory 127A. Those descriptions will not be repeated here.

The storage 241 can be a non-transitory storage medium that stores data for providing the functionality described herein. The storage 241 may be a DRAM device, a SRAM device, flash memory, or some other memory devices. In some embodiments, the storage 241 also includes a non-volatile memory or similar permanent storage device and media (e.g., a hard disk drive, a floppy disk drive, a flash memory device, etc.) for storing information on a more permanent basis.

In the illustrated embodiment shown in FIG. 2, the AI platoon system 141 includes: a communication module 202; the AI manager 143; and the platoon manager 144. These components of the AI platoon system 141 are communicatively coupled to each other via the bus 220. In some embodiments, components of the AI platoon system 141 can be stored in a single server or device. In some other embodiments, components of the AI platoon system 141 can be distributed and stored across multiple servers or devices.

The communication module 202 can be software including routines for handling communications between the AI platoon system 141 and other components of the computer system 200. In some embodiments, the communication module 202 can be stored in the memory 127A of the computer system 200 and can be accessible and executable by the processor 125A. The communication module 202 may be adapted for cooperation and communication with the processor 125A and other components of the computer system 200 via a signal line 222.

The communication module 202 sends and receives data, via the communication unit 145A, to and from one or more elements of the operating environment 100. For example, the communication module 202 transmits, via the communication unit 145A, instruction data describing an instruction to execute a vehicle platooning maneuver at a particular area to the vehicle 110. The communication module 202 may send or receive any of the data or messages described above with reference to FIG. 1 via the communication unit 145A.

In some embodiments, the communication module 202 receives data from the other components of the AI platoon system 141 and stores the data in one or more of the storage 241 and the memory 127A. The other components of the AI platoon system 141 may cause the communication module 202 to communicate with the other elements of the computer system 200 or the operating environment 100 (via the communication unit 145A). For example, the AI manager 143 or the platoon manager 144 may use the communication module 202 to communicate with the simulation software 147 and cause the simulation software 147 to run simulations for a vehicle platooning maneuver.

The AI manager 143 can be software including routines for determining an area to execute a maneuver based on hierarchical AI data. In some embodiments, the AI manager 143 can be stored in the memory 127A of the computer system 200 and can be accessible and executable by the processor 125A. The AI manager 143 may be adapted for cooperation and communication with the processor 125A and other components of the computer system 200 via a signal line 224.

In some embodiments, the AI manager 143 receives sensor data from the vehicle 110 as well as other endpoints in the roadway environment (e.g., other vehicles, roadside units, etc.). The AI manager 143 aggregates the received sensor. The AI manager 143 may determine current traffic information (e.g., real-time traffic information) based on the aggregated sensor data. The AI manager 143 may also determine predicted future traffic information based at least in part on the aggregated sensor data. Then, the AI manager 143 generates hierarchical AI data that describes one or more of the following: real-life traffic information; real-time traffic information; and predicted future traffic information.

In some embodiments, the AI manager 143 receives a request to execute a vehicle platooning maneuver from the vehicle 110 operating in a roadway environment. In some examples, the request may include a platoon identifier (ID) that identifies a vehicle platoon for an execution of the vehicle platooning maneuver. For example, the vehicle platooning maneuver may be an exit maneuver and the request includes a platoon ID of a vehicle platoon that the vehicle 110 plans to exit from.

In some other examples, the request does not identify any vehicle platoon to execute the vehicle platooning maneuver, and the AI manager 143 may identify a vehicle platoon to execute the vehicle platooning maneuver for the vehicle 110. For example, the request includes an entrance maneuver. The AI manager 143 determines a set of vehicle platoons available in the roadway environment based on current platoon information of the roadway environment. The AI manager 143 selects a vehicle platoon from the set of vehicle platoons to execute the vehicle platooning maneuver because a destination of the vehicle platoon and a destination of the vehicle 110 are in a same geographic location.

The AI manager 143 may determine a set of candidate areas in the roadway environment for executing the vehicle platooning maneuver. In some embodiments, the AI manager 143 determines the set of candidate areas based on one or more of: the hierarchical AI data; roadway information (e.g., roadway structures); weather information; or any combination thereof. For example, based on the real-time traffic information and the predicted future traffic information, the AI manager 143 may determine a set of candidate areas in the roadway environment where the vehicle platoon and the vehicle 110 can meet one another.

In some examples, the set of candidate areas can include one or more locations with least traffic. In some examples, the set of candidate areas can include one or more locations each having sufficient space to execute the vehicle platooning maneuver (e.g., locations with no sharp turns, locations with multiple lanes in each direction, etc.). It is understood that the set of candidate locations can include any other location that is suitable to execute the vehicle platooning maneuver.

Next, the AI manager 143 may use the simulation software 147 to execute a simulation that implements the vehicle platooning maneuver at the set of candidate areas respectively. For example, the AI manager 143 may run a digital twin simulation that implements the vehicle platooning maneuver at the set of candidate areas respectively. The simulation can be seeded with the hierarchical AI data.

The AI manager 143 selects, from the set of candidate areas, a candidate area where an execution of the vehicle platooning maneuver in the simulation satisfies one or more platooning requirements. Examples of a platooning requirement may include a safety-guarantee requirement (e.g., the maneuver being executed safely), a successful-execution requirement (e.g., the maneuver being completed successfully) or any other requirement. For example, based on a simulation result, the AI manager 143 selects a candidate area where the vehicle platooning maneuver can be performed safely and successfully in the simulation. Then, the AI manager 143 determines the candidate area as an area in the roadway environment where the vehicle platooning maneuver is executed. The AI manager 143 may inform the platoon manager 144 and the AI client 199 of the vehicle 110 about the area where the vehicle platooning maneuver is executed.

In some embodiments, the request received from the vehicle 110 may already identify a location to execute the vehicle platooning maneuver. The AI manager 143 may determine whether it is safe to execute the vehicle platooning maneuver at the identified location. For example, the AI manager 143 uses the simulation software 147 to execute a simulation that implements the vehicle platooning maneuver at the location and generates a simulation result. If the simulation result indicates that it is unsafe to execute the vehicle platooning maneuver at the location, the AI manager 143 may reject to execute the vehicle platooning maneuver at the identified location. Then, the AI manager 143 may perform operations similar to those described above to determine an area to execute the vehicle platooning maneuver for the vehicle 110.

In some embodiments, as described below in more detail, the platoon manager 144 may determine to execute a platoon reconfiguration maneuver on a vehicle platoon. The platoon reconfiguration maneuver may include a set of vehicle platooning maneuvers to be performed. Then, for each vehicle platooning maneuver, the AI manager 143 may determine an area in the roadway environment to execute the vehicle platooning maneuver by performing operations similar to those described above. As a result, the AI manager 143 determines a set of areas in the roadway environment to execute the set of vehicle platooning maneuvers included in the platoon reconfiguration maneuver.

The platoon manager 144 can be software including routines for managing vehicle platoons. In some embodiments, the platoon manager 144 can be stored in the memory 127A of the computer system 200 and can be accessible and executable by the processor 125A. The platoon manager 144 may be adapted for cooperation and communication with the processor 125A and other components of the computer system 200 via a signal line 226.

In some embodiments, the platoon manager 144 maintains mobility information, configuration information or any other type of information of the vehicle platoons available in the roadway environment. The mobility information of a vehicle platoon may include location information of the vehicle platoon (e.g., an absolute coordinate or a relative position of the vehicle platoon). The configuration information of the vehicle platoon may include types of vehicles in the vehicle platoon, an order of the vehicles in the vehicle platoon, and one or more resources (e.g., computing resources, network resources, etc.) available in the vehicles, etc.

For each vehicle platoon managed by the platoon manager 144, the platoon manager 144 may determine a navigation path for the vehicle platoon. For example, the platoon manager 144 may determine a navigation path for the vehicle platoon based on destination information of member vehicles in the vehicle platoon.

In some scenarios, the platoon manager 144 may also determine one or more vehicle platooning maneuvers to be executed on the vehicle platoon. For example, the platoon manager 144 may instruct the AI manager 143 to determine one or more areas along the navigation path to execute one or more exit maneuvers. The platoon manager 144 then instructs the leader vehicle to execute the one or more exit maneuvers at the one or more areas so that the member vehicles may exit from the vehicle platoon at the one or more areas respectively.

For each vehicle platoon managed by the platoon manager 144, the platoon manager 144 may carry out an execution of a vehicle platooning maneuver that is to be performed on the vehicle platoon. For example, the platoon manager 144 may generate a first instruction to instruct a leader vehicle of the vehicle platoon to re-route the vehicle platoon to an area where the vehicle platooning maneuver is to be executed. If the vehicle 110 is already a member vehicle of the vehicle platoon, then the vehicle 110 is also rerouted to the area. However, if the vehicle 110 is not a member vehicle of the vehicle platoon, the platoon manager 144 may generate a second instruction to instruct the vehicle 110 to re-route to the area. When the vehicle platoon (as well as the vehicle 110) arrives at the area, the platoon manager 144 may instruct the leader vehicle (as well as the vehicle 110) to execute the vehicle platooning maneuver at the area. The platoon manager 144 may also monitor an execution status of the vehicle platooning maneuver.

For each or a particular vehicle platoon managed by the platoon manager 144, the platoon manager 144 may determine whether to reconfigure the vehicle platoon after a vehicle platooning maneuver is executed on the vehicle platoon so that one or more goals are satisfied. The one or more goals may include, for example, an achievement of a maximum efficiency, an improvement of driving safety or any other goals. The platoon manager 144 may determine how to reconfigure the vehicle platoon so that the one or more goals are satisfied. For example, after an execution of a vehicle platooning maneuver, a configuration of the vehicle platoon may not be efficient anymore. In this case, the platoon manager 144 may determine to reconfigure the vehicle platoon so that a maximum efficiency is achieved in the vehicle platoon.

Specifically, the platoon manager 144 may determine a platoon reconfiguration maneuver that includes a set of consecutive vehicle platooning maneuvers used to reconfigure the vehicle platoon. In some examples, the platoon reconfiguration maneuver may reorder the member vehicles in the vehicle platoon (e.g., a splitting maneuver following by a merging maneuver). For example, the platoon reconfiguration maneuver reorders the member vehicles so that a truck located at the rear can be changed to travel in the front to achieve a better fuel efficiency.

In some examples, the platoon reconfiguration maneuver may include re-electing a new leader vehicle based on available resources. For example, a vehicle with better resources (data storage, sensor resources, communication resources, etc.) joins the vehicle platoon, and the platoon manager 144 may assign the vehicle as a new leader vehicle of the vehicle platoon. In this case, the platoon manager 144 may also reorder the vehicles in the vehicle platoon so that a position of the vehicle can be changed to a better location to lead the vehicle platoon.

The platoon manager 144 may instruct the AI manager 143 to determine a set of areas for executing the set of vehicle platooning maneuvers included in the platoon reconfiguration maneuver. Then, the platoon manager 144 may instruct the vehicle platoon (e.g., the leader vehicle) to carry out the execution of the platoon reconfiguration maneuver at the set of areas. The platoon manager 144 may also monitor an execution status of the platoon reconfiguration maneuver.

In some embodiments, the set of areas can be a same area so that the set of vehicle platooning maneuvers in the platoon reconfiguration maneuver can be executed in the same area. In some other embodiments, the set of areas can be two or more different areas so that the set of vehicle platooning maneuvers in the platoon reconfiguration maneuver can be executed in the two or more different areas.

From the above description for FIG. 2, it can be seen that the AI platoon system 141 can determine a set of candidate areas for executing a vehicle platooning maneuver using hierarchical AI data. An execution of the vehicle platooning maneuver may involve a vehicle platoon and the vehicle 110. The AI platoon system 141 can simulate the execution of the vehicle platooning maneuver at the set of candidate areas based on the hierarchical AI data and determine an area to execute the vehicle platooning maneuver based on a simulation result. The AI platoon system 141 may navigate the vehicle platoon (as well as the vehicle 110) to the area to execute the vehicle platooning maneuver. The execution of the vehicle platooning maneuver at the area does not violate a destination of the vehicle platoon as well as a destination of the vehicle 110. In this case, stability of the vehicle platoon can be improved with guaranteed safety.

For example, assume that the vehicle platooning maneuver is an entrance maneuver requested from the vehicle 110. The AI platoon system 141 can select an existing vehicle platoon or create a new vehicle platoon to execute the entrance maneuver and determine a location to perform the entrance maneuver based on the hierarchical AI data. The AI platoon system 141 may instruct the vehicle platoon and the vehicle 110 to navigate to the location respectively so that the vehicle 110 can join the vehicle platoon at the location.

The AI platoon system 141 may also measure an efficiency of the vehicle platoon and optimize the efficiency. For example, the efficiency can be evaluated in terms a desired speed, a travel time, a travel distance, a fuel consumption, or any combination thereof. The AI platoon system 141 may determine a platoon reconfiguration maneuver to be performed on the vehicle platoon to achieve a maximum efficiency. The AI platoon system 141 can determine one or more locations to perform the platoon reconfiguration maneuver. For example, the platoon reconfiguration maneuver may include one or more vehicle platooning maneuvers, and the one or more vehicle platooning maneuvers can be executed at the one or more locations respectively. The AI platoon system 141 may instruct the vehicle platoon to navigate to the one or more locations respectively so that the one or more vehicle platooning maneuvers in the platoon reconfiguration maneuver are executed at the one or more locations.

### Example Processes

Referring now to FIG. 3, depicted is a flowchart of an example method 300 for managing a vehicle platoon according to some embodiments. The steps of the method 300 are executable in any order, and not necessarily the order depicted in FIG. 3.

At step 303, the AI manager 143 receives a request to execute a vehicle platooning maneuver from the vehicle 110 operating in a roadway environment.

At step 305, the AI manager 143 executes a simulation.

At step 307, the AI manager 143 determines an area in the roadway environment where the vehicle platooning maneuver is executed based on the simulation.

At step 309, the platoon manager 144 instructs the vehicle 110 to execute the vehicle platooning maneuver at the area.

In some embodiments, the vehicle 110 is an autonomous vehicle.

In some embodiments, the simulation is a digital twin simulation. The simulation is seeded with hierarchical AI data that describes one or more of the following: real-life traffic information; real-time traffic information; and predicted future traffic information.

In some embodiments, the method 300 can be executed by at least one processor-based computing device selected from the following set of processor-based computing devices: an onboard unit of a leader vehicle of a vehicle platoon; and the server 140.

In some embodiments, after the vehicle platooning maneuver is executed on a vehicle platoon, the platoon manager 144 further determines whether to reconfigure the vehicle platoon so that one or more goals are satisfied. In some embodiments, after the vehicle platooning maneuver is executed on the vehicle platoon, the platoon manager 144 further determines how to reconfigure the vehicle platoon so that the one or more goals are satisfied.

In some embodiments, the AI manager 143 executes the simulation at least by performing one or more of the following operations. For example, the AI manager 143 determines a set of candidate areas in the roadway environment for executing the vehicle platooning maneuver. The AI manager 143 executes the simulation to implement the vehicle platooning maneuver at the set of candidate areas respectively. The AI manager 143 selects, from the set of candidate areas, a candidate area where an execution of the vehicle platooning maneuver in the simulation satisfies one or more platooning requirements. The AI manager 143 determines the candidate area as the area in the roadway environment where the vehicle platooning maneuver is executed.

FIGS. 4A-4B depict another method 400 for managing a vehicle platoon according to some embodiments. The steps of the method 400 are executable in any order, and not necessarily the order depicted in FIGS. 4A-4B.

Referring to FIG. 4A, at step 401, the AI manager 143 receives a request to execute a vehicle platooning maneuver from the vehicle 110 operating in a roadway environment.

At step 403, the platoon manager 144 determines platoon information and maneuver information in the roadway environment.

At step 405, the AI manager 143 determines hierarchical AI data associated with the roadway environment.

At step 407, the AI manager 143 determines a vehicle platoon and a set of candidate areas in the roadway environment for executing the vehicle platooning maneuver based on the platoon information and the hierarchical AI data. For example, for an entrance maneuver, the AI manager 143 may determine a vehicle platoon to execute the entrance maneuver so that the vehicle 110 can join the vehicle platoon.

At step 409, the AI manager 143 determines whether there are one or more first candidate areas where an execution of the vehicle platooning maneuver is safe from the set of candidate areas. For example, the AI manager 143 may run a simulation to determine whether the execution of the vehicle platooning maneuver is safe at the one or more first candidate areas. Responsive to there being one or more first candidate areas where the execution of the vehicle platooning maneuver is safe, the method 400 moves to step 412. Otherwise, the method 400 moves to step 410.

In some embodiments, the safe execution of the vehicle platooning maneuver at the one or more first candidate areas satisfies a safety-guarantee requirement. The one or more first candidate areas are a subset of the set of candidate areas.

At step 410, the AI manager 143 temporarily rejects the request. Then, at step 411, the AI manager 143 determines whether a predetermined period of time elapses. Responsive to determining that the predetermined period of time has not elapsed, the method 400 moves back to step 411 to wait for the predetermined period of time to elapse. Responsive to determining that the predetermined period of time has elapsed, the method 400 moves to step 403 again to determine the platoon information in the roadway environment and continues to execute steps 405, 407 and 409 as described above.

For example, assume that the vehicle 110 waits to join a vehicle platoon at an entrance of a roadway. The request to execute an entrance maneuver from the vehicle 110 is initially rejected by the AI manager 143 at step 410 because temporarily there is no safe area on the roadway to execute the entrance maneuver. Then, after the predetermined period of time has elapsed, some new vehicle platoons may travel to the roadway while some vehicle platoons may leave from the roadway. The hierarchical AI data in the roadway environment is also updated due to changes on the traffic. Then, the AI manager 143 may determine whether there are one or more first candidate areas to execute the entrance maneuver safely at step 409 again.

At step 412, the AI manager 143 executes a simulation to implement the vehicle platooning maneuver at the one or more first candidate areas respectively.

At step 413, the AI manager 143 determines whether there are one or more second candidate areas from the one or more first candidate areas where the execution of the vehicle platooning maneuver in the simulation is performed successfully. Responsive to there being one or more second candidate areas where the execution of the vehicle platooning maneuver in the simulation is performed successfully, the method 400 moves to step 415. Otherwise, the method 400 moves back to step 410.

In some embodiments, the successful execution of the vehicle platooning maneuver at the one or more second candidate areas satisfies a successful-execution requirement. The one or more second candidate areas are a subset of the one or more first candidate areas.

Referring to FIG. 4B, at step 415, the AI manager 143 selects a candidate area from the one or more second candidate areas to be an area in the roadway environment where the vehicle platooning maneuver is executed. For example, the selected candidate area can be a candidate area closest to the vehicle 110 (or closest to the vehicle platoon) when compared to other second candidate areas.

At step 417, the platoon manager 144 instructs the vehicle 110 and the vehicle platoon to navigate to the area for the execution of the vehicle platooning maneuver.

At step 419, the platoon manager 144 determines whether to reconfigure the vehicle platoon so that one or more goals are satisfied. Responsive to determining to reconfigure the vehicle platoon, the method 400 moves to step 421. Otherwise, the method 400 ends.

At step 421, the platoon manager 144 determines a platoon reconfiguration maneuver for reconfiguring the vehicle platoon.

At step 423, the platoon manager 144 executes the platoon reconfiguration maneuver on the vehicle platoon so that the one or more goals are satisfied.

Referring to FIG. 5A, an example architecture 500 for the AI platoon system 141 and the AI client 199 is illustrated. The AI platoon system 141 may be installed in the server 140 or a leader vehicle of a vehicle platoon. The vehicle 110 may generate a request to execute a vehicle platooning maneuver on the vehicle platoon. For example, the vehicle 110 may generate a request to execute an entrance maneuver to join the vehicle platoon. In another example, the vehicle 110 is already a member vehicle of the vehicle platoon, and the vehicle 110 may generate a request to execute an exit maneuver to exit from the vehicle platoon.

Besides the elements described above with reference to FIG. 1, the vehicle 110 may also include a data storage 515, a network interface 517, a vehicle manager 511 and a vehicle platoon manager 513.

The vehicle manager 511 may include code and routines for performing coordination with other vehicles 110 (non-platooned) via V2X communications. For example, the vehicle manager 511 may manage (e.g., establish and maintain) inter-vehicular wireless links and control executions of collaborative operations among the vehicles 110.

The vehicle platoon manager 513 may include code and routines for performing coordination with other member vehicles that are in the same vehicle platoon as the vehicle 110. For example, the vehicle platoon manager 513 propagates a request received from a first member vehicle to a second member vehicle or the server 140. The vehicle platoon manager 513 instructs the vehicle 110 to follow a leader vehicle of the vehicle platoon with a minimum speed variation and a minimum distance variation. The vehicle platoon manager 513 may follow one or more instructions received from the AI client 199 and execute one or more actions indicated by the one or more instructions.

The AI client 199 of the vehicle 110 may cause the vehicle manager 511 to send sensor data recorded by the vehicle 110 to the AI platoon system 141. The AI client 199 may generate the request to execute the vehicle platooning maneuver. The AI client 199 informs, via the vehicle manager 511, the platoon manager 144 and the AI manager 143 about the request to execute the vehicle platooning maneuver.

Turning to the platoon manager 144, in some embodiments the platoon manager 144 may include one or more of the following elements: a platoon mobility planner 505; a platoon route planner 507; and a platoon maneuver planner 509.

The platoon mobility planner 505 may be operable to monitor information of vehicle platoons present in the roadway environment. This information may include, but is not limited to, one or more of the following: mobility information; configuration information; and any other platoon information.

The platoon route planner 507 may be operable to perform a route planning for the vehicle platoon based on destination information of the vehicles in the vehicle platoon. For example, the route planning may include a planning of a navigation path for the vehicle platoon. The route planning may also include a determination of one or more locations along the navigation path so that one or more vehicle platooning maneuvers can be executed at the one or more locations. For example, the route planning includes a determination of a set of locations along the navigation path to execute exit maneuvers so that the member vehicles may exit from the vehicle platoon at the set of locations respectively. In some embodiments, the platoon route planner 507 may instruct the AI manager 143 to determine the set of locations based on hierarchical AI data.

The platoon maneuver planner 509 may be operable to manage vehicle platooning maneuvers for member vehicles in the vehicle platoon. For example, the platoon maneuver planner 509 may utilize a current route and mobility information of the vehicle platoon and hierarchical AI data received from the AI manager 143 to simulate an execution of a vehicle platooning maneuver on the vehicle platoon. The platoon maneuver planner 509 may determine whether it is safe to perform the vehicle platooning maneuver based on the simulation. The platoon maneuver planner 509 may also track an execution of the vehicle platooning maneuver (e.g., monitoring an execution status of the vehicle platooning maneuver).

The platoon maneuver planner 509 may also be operable to monitor a configuration of the vehicle platoon and manage an execution of a platoon reconfiguration maneuver in the vehicle platoon.

Turning to the AI manager 143, in some embodiments the AI manager 143 may include one or more of the following elements: an AI mobility planner 501; and an AI route planner 503.

The AI mobility planner 501 is operable to continuously monitor mobility information of connected vehicles and store current route information and predicted route information of the connected vehicles. The AI mobility planner 501 may generate the hierarchical AI data based at least on the current route information and predicted route information of the connected vehicles and any other information of the connected vehicles (e.g., speed data, heading data, etc.).

The AI mobility planner 501 may receive platoon information (e.g., describing one or more vehicle platoons available in the roadway environment) and maneuver information (e.g., describing a vehicle platooning maneuver to be performed) from the platoon manager 144. The AI mobility planner 501 may instruct the AI route planner 503 to search for a location to execute the vehicle platooning maneuver so that an execution of the vehicle platooning maneuver at the location satisfies one or more platooning requirements. The AI route planner 503 is operable to search for the location to execute the vehicle platooning maneuver based on data received from the AI mobility planner 501 such as the hierarchical AI data.

In some embodiments, the AI route planner 503 may instruct the vehicle platoon and the vehicle 110 to navigate to the location respectively so that they meet each other at the location and the vehicle platooning maneuver can be executed at the location. In this case, the AI route planner 503 may generate a first instruction to instruct the vehicle platoon to navigate to the location for the execution of the vehicle platooning maneuver. The AI route planner 503 may also generate a second instruction to instruct the vehicle 110 to navigate to the location for the execution of the vehicle platooning maneuver. The first instruction is sent to the leader vehicle of the vehicle platoon, and the second instruction is sent to the vehicle 110.

In some other embodiments, the AI mobility planner 501 may inform the platoon manager 144 about the location so that the platoon manager 144 can instruct the vehicle platoon as well as the vehicle 110 to execute the vehicle platooning maneuver at the location. In this case, the platoon manager 144 (rather than the AI route planner 503) may generate the first instruction to instruct the vehicle platoon to navigate to the location for the execution of the vehicle platooning maneuver. The platoon manager 144 (rather than the AI route planner 503) may also generate the second instruction to instruct the vehicle 110 to navigate to the location for the execution of the vehicle platooning maneuver. The first instruction is sent to the leader vehicle of the vehicle platoon, and the second instruction is sent to the vehicle 110.

After receiving the second instruction to execute the vehicle platooning maneuver at the location, the AI client 199 of the vehicle 110 may inform the vehicle platoon manager 513 about the received instruction. The AI client 199 ensures that the vehicle platoon manager 513 follows the instruction to navigate the vehicle 110 to the location and complete the vehicle platooning maneuver at the location. The AI client 199 also stores data describing the location and one or more actions for executing the vehicle platooning maneuver.

FIG. 5B is a graphical representation illustrating an example approach 550 for learning hierarchical AI data according to some embodiments. In the example approach 550, the hierarchical AI data is learned hierarchically from large scale and fragmented vehicle data (e.g., sensor data from vehicles) in real time. The vehicles can include connected vehicles 551 and non-connected vehicles 553.

Various types of vehicle data are collected including, but not limited to, instrumentation data, logging data, sensor data or any other type of data. Reliable streams of data can be stored in data storages (either structured or unstructured data storages) so that a reliable data flow is established.

The data collected through the reliable data flow is explored and transformed via, e.g., data cleaning and data preparation, etc. Any missing data in the data flow can be identified.

Business intelligence can be used to define metrics to track and evaluate the data. For example, various analytics methods and different metrics can be used to evaluate the data. The data can be aggregated and labeled. Features of the data can be extracted and used as training data. After a series of operations are performed on the data, the data can be modeled using one or more data models.

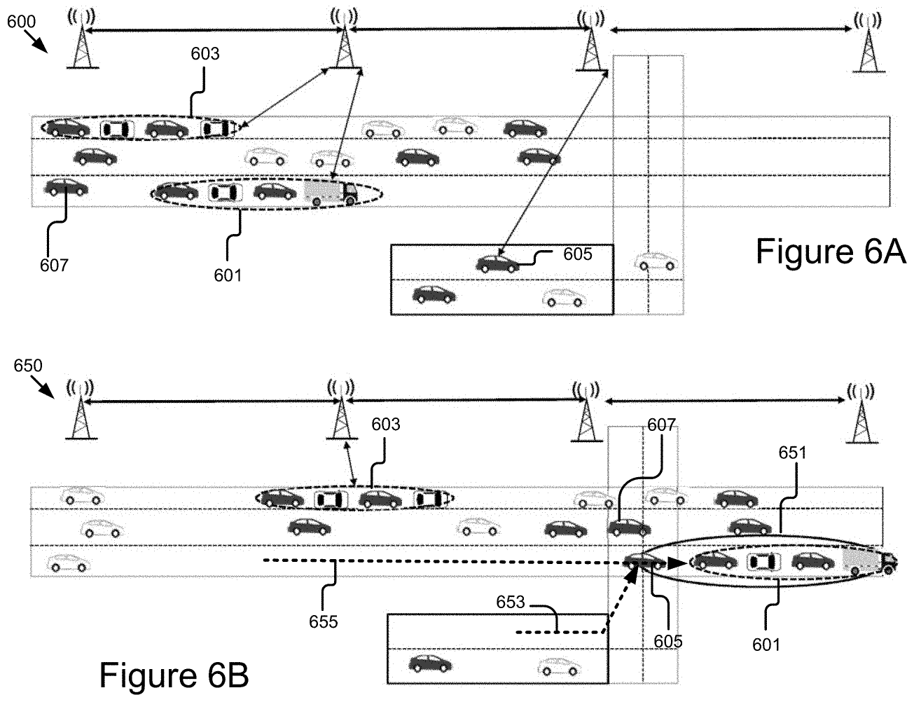

FIGS. 6A-6B are graphical representations 600 and 650 illustrating an example of managing a vehicle platoon with a vehicle platooning maneuver according to some embodiments. In this example, two vehicle platoons 601 and 603 and various vehicles including vehicles 605 and 607 are present in a roadway environment. The various vehicles may include connected vehicles and non-connected vehicles. Here, the vehicle platooning maneuver is an entrance maneuver, and the vehicle 605 sends a request to execute the entrance maneuver so that it can join a vehicle platoon.

Referring to FIG. 6A, the AI platoon system 141 receives the request from the vehicle 605, and determines one or more available vehicle platoons (e.g., the vehicle platoons 601 and 603) in the roadway environment. The AI platoon system 141 may select the vehicle platoon 601 from the one or more available vehicle platoons to execute the entrance maneuver. For example, the vehicle platoon 601 is in a lane closer to the vehicle 605 than the vehicle platoon 603, and so, it is more convenient for the vehicle platoon 601 to execute the entrance maneuver when compared to the vehicle platoon 603. However, if there is no vehicle platoon available in the roadway environment, the AI platoon system 141 may initiate a construction of a new vehicle platoon so that the vehicle 110 can join the newly constructed vehicle platoon.

The AI platoon system 141 may generate hierarchical AI data of the roadway environment and determine a set of candidate areas to execute the entrance maneuver on the vehicle platoon 601 based on the hierarchical AI data. The AI platoon system 141 may simulate an execution of the entrance maneuver at the set of candidate areas using the hierarchical AI data. The AI platoon system 141 may determine, from the set of candidate areas, an area to execute the entrance maneuver such that the execution of the entrance maneuver at the area is safe and successful in the simulation.

Referring to FIG. 6B, an area 651 is determined for an execution of the entrance maneuver. The AI platoon system 141 instructs the vehicle platoon 601 to navigate to the area 651 via a path 655 and the vehicle 605 to navigate to the area 651 via a path 653, so that the entrance maneuver is executed safely and successfully at the area 651. Because the vehicle 607 that is behind the vehicle platoon 601 in FIG. 6A may block a re-routing of the vehicle 605 along the path 653, the AI platoon system 141 may instruct the vehicle 607 to change to another lane (as shown in FIG. 6B). As a result, the execution of the entrance maneuver at the area 651 is ensured to be safe and successful.

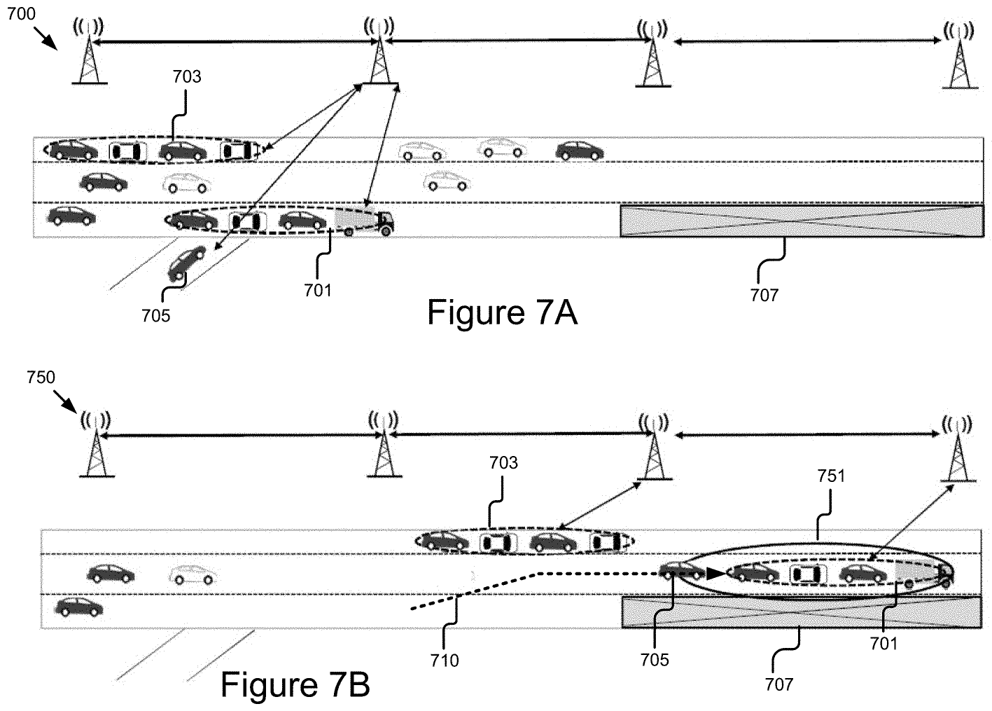

FIGS. 7A-7B are graphical representations 700 and 750 illustrating another example of managing a vehicle platoon with a vehicle platooning maneuver according to some embodiments. In this example, two vehicle platoons 701 and 703 and various vehicles including a vehicle 705 are present in a roadway environment. A lane where the vehicle platoon 701 travels is closed ahead (as shown by a blockage 707). Here, the vehicle platooning maneuver is an entrance maneuver, and the vehicle 705 sends a request to execute the entrance maneuver at a proposed location (e.g., an entrance of the roadway) so that it can join a vehicle platoon.

Referring to FIG. 7A, the AI platoon system 141 receives the request from the vehicle 705, and determines one or more available vehicle platoons (e.g., the vehicle platoons 701 and 703) in the roadway environment. The AI platoon system 141 may select the vehicle platoon 701 from the one or more available vehicle platoons to execute the entrance maneuver.

The AI platoon system 141 may simulate an execution of the entrance maneuver at the proposed location to determine whether it is safe to execute the entrance maneuver at the proposed location. In this example, because the lane where the vehicle platoon 701 travels is closed ahead, it is unsafe to execute the entrance maneuver at the proposed location (e.g., the entrance of the roadway). Then, the AI platoon system 141 rejects to execute the entrance maneuver at the proposed location.

Next, the AI platoon system 141 may generate hierarchical AI data of the roadway environment and determine a set of candidate areas to execute the entrance maneuver on the vehicle platoon 701 based on the hierarchical AI data. The AI platoon system 141 may simulate an execution of the entrance maneuver at the set of candidate areas using the hierarchical AI data. The AI platoon system 141 may determine, from the set of candidate areas, an area to execute the entrance maneuver such that the execution of the entrance maneuver at the area is safe and successful in the simulation.

Referring to FIG. 7B, an area 751 is determined for an execution of the entrance maneuver. The AI platoon system 141 instructs the vehicle platoon 701 to navigate to the area 751 via a path 710. The AI platoon system 141 also instructs the vehicle 705 to navigate to the area 751. As a result, the entrance maneuver is executed safely and successfully at the area 751.

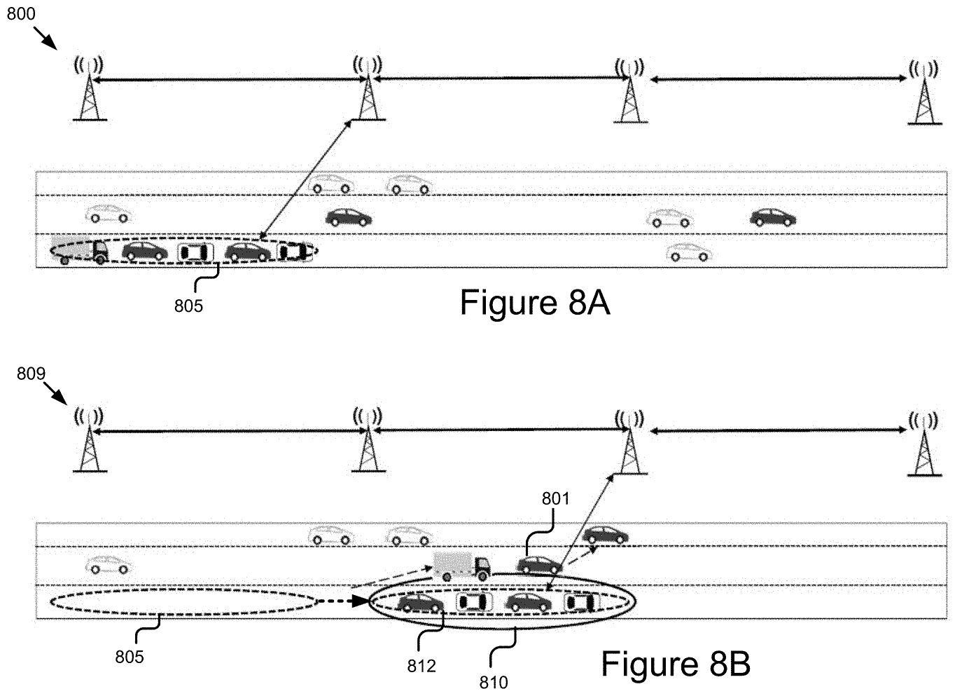

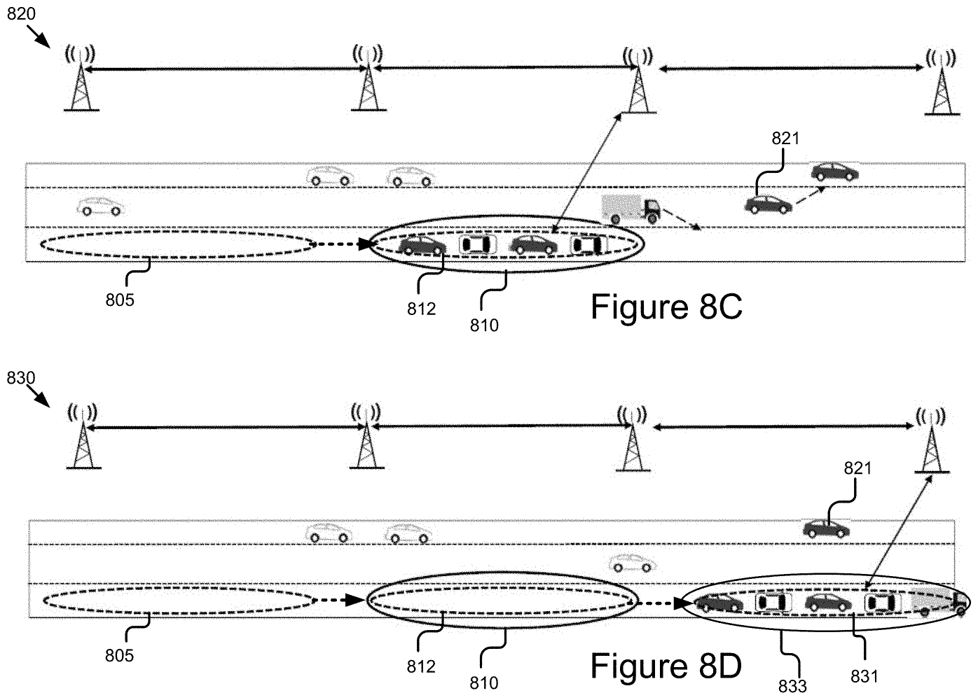

FIGS. 8A-8D are graphical representations 800, 809, 820 and 830 illustrating an example of managing a vehicle platoon with a platoon reconfiguration maneuver according to some embodiments. In this example, a vehicle platoon 805 and various vehicles are present in a roadway environment.

Referring to FIG. 8A, the AI platoon system 141 checks the vehicle platoon 805 and explores a possible reconfiguration of the vehicle platoon 805 to achieve a maximum efficiency. For example, the reconfiguration may include a reordering of vehicles in the vehicle platoon 805, updating a leader vehicle in the vehicle platoon 805 or a combination thereof. The AI platoon system 141 may determine a platoon reconfiguration maneuver to achieve the reconfiguration. For example, the platoon reconfiguration maneuver may include one or more vehicle platooning maneuvers.

The AI platoon system 141 may determine one or more areas to execute the one or more vehicle platooning maneuvers of the platoon reconfiguration maneuver based on hierarchical AI data of the roadway environment. The AI platoon system 141 may simulate the platoon reconfiguration maneuver (e.g., by simulating an execution of the one or more vehicle platooning maneuvers at the one or more areas) to verify whether the maximum efficiency can be achieved. Responsive to the maximum efficiency being achieved in the simulation, the AI platoon system 141 may instruct the vehicle platoon 805 to actually carry out the platoon reconfiguration maneuver.

For example, assume that the reconfiguration of the vehicle platoon 805 includes a reordering of vehicles in the platoon so that a truck at the rear can be positioned in the front of the platoon. The platoon reconfiguration maneuver includes a splitting maneuver followed by a merging maneuver. The AI platoon system 141 determines to execute the splitting maneuver at an area 810 shown in FIG. 8B and the merging maneuver at an area 833 shown in FIG. 8D.

Referring to FIG. 8B, an execution of the splitting maneuver is shown. The AI platoon system 141 navigates the vehicle platoon 805 to the area 810, and then splits the vehicle platoon 805 into a vehicle platoon 812 and the truck at the area 810. A vehicle 801 traveling ahead of the truck may be rerouted to another lane so that the splitting maneuver can be executed properly and safely at the area 810.

Referring to FIG. 8C, after the execution of the splitting maneuver, the AI platoon system 141 may instruct the truck to travel ahead of the vehicle platoon 812. A vehicle 821 traveling ahead of the truck may be rerouted to another lane so that the next merging maneuver can be executed properly and safely at the area 833.

Referring to FIG. 8D, an execution of the merging maneuver is shown. The AI platoon system 141 navigates the vehicle platoon 812 and the truck to the area 833, and then merges the vehicle platoon 812 with the truck at the area 833 to form a new vehicle platoon 831. In the vehicle platoon 831, the truck travels in the front of the platoon.

In the above description, for purposes of explanation, numerous specific details are set forth in order to provide a thorough understanding of the specification. It will be apparent, however, to one skilled in the art that the disclosure can be practiced without these specific details. In some instances, structures and devices are shown in block diagram form in order to avoid obscuring the description. For example, the present embodiments can be described above primarily with reference to user interfaces and particular hardware. However, the present embodiments can apply to any type of computer system that can receive data and commands, and any peripheral devices providing services.

Reference in the specification to “some embodiments” or “some instances” means that a particular feature, structure, or characteristic described in connection with the embodiments or instances can be included in at least one embodiment of the description. The appearances of the phrase “in some embodiments” in various places in the specification are not necessarily all referring to the same embodiments.

Some portions of the detailed descriptions that follow are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout the description, discussions utilizing terms including “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission, or display devices.

The present embodiments of the specification can also relate to an apparatus for performing the operations herein. This apparatus may be specially constructed for the required purposes, or it may include a general-purpose computer selectively activated or reconfigured by a computer program stored in the computer. Such a computer program may be stored in a computer-readable storage medium, including, but is not limited to, any type of disk including floppy disks, optical disks, CD-ROMs, and magnetic disks, read-only memories (ROMs), random access memories (RAMs), EPROMs, EEPROMs, magnetic or optical cards, flash memories including USB keys with non-volatile memory, or any type of media suitable for storing electronic instructions, each coupled to a computer system bus.

The specification can take the form of some entirely hardware embodiments, some entirely software embodiments or some embodiments containing both hardware and software elements. In some preferred embodiments, the specification is implemented in software, which includes, but is not limited to, firmware, resident software, microcode, etc.

Furthermore, the description can take the form of a computer program product accessible from a computer-usable or computer-readable medium providing program code for use by or in connection with a computer or any instruction execution system. For the purposes of this description, a computer-usable or computer-readable medium can be any apparatus that can contain, store, communicate, propagate, or transport the program for use by or in connection with the instruction execution system, apparatus, or device.

A data processing system suitable for storing or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including, but not limited, to keyboards, displays, pointing devices, etc.) can be coupled to the system either directly or through intervening I/O controllers.

Network adapters may also be coupled to the system to enable the data processing system to become coupled to other data processing systems or remote printers or storage devices through intervening private or public networks. Modems, cable modem, and Ethernet cards are just a few of the currently available types of network adapters.

Finally, the algorithms and displays presented herein are not inherently related to any particular computer or other apparatus. Various general-purpose systems may be used with programs in accordance with the teachings herein, or it may prove convenient to construct more specialized apparatus to perform the required method steps. The required structure for a variety of these systems will appear from the description below. In addition, the specification is not described with reference to any particular programming language. It will be appreciated that a variety of programming languages may be used to implement the teachings of the specification as described herein.

The foregoing description of the embodiments of the specification has been presented for the purposes of illustration and description. It is not intended to be exhaustive or to limit the specification to the precise form disclosed. Many modifications and variations are possible in light of the above teaching. It is intended that the scope of the disclosure be limited not by this detailed description, but rather by the claims of this application. As will be understood by those familiar with the art, the specification may be embodied in other specific forms without departing from the spirit or essential characteristics thereof. Likewise, the particular naming and division of the modules, routines, features, attributes, methodologies, and other aspects are not mandatory or significant, and the mechanisms that implement the specification or its features may have different names, divisions, or formats. Furthermore, as will be apparent to one of ordinary skill in the relevant art, the modules, routines, features, attributes, methodologies, and other aspects of the disclosure can be implemented as software, hardware, firmware, or any combination of the three. Also, wherever a component, an example of which is a module, of the specification is implemented as software, the component can be implemented as a standalone program, as part of a larger program, as a plurality of separate programs, as a statically or dynamically linked library, as a kernel-loadable module, as a device driver, or in every and any other way known now or in the future to those of ordinary skill in the art of computer programming. Additionally, the disclosure is in no way limited to embodiment in any specific programming language, or for any specific operating system or environment. Accordingly, the disclosure is intended to be illustrative, but not limiting, of the scope of the specification, which is set forth in the following claims.

What is claimed is:

1. A computer program product comprising a non-transitory memory of a computer system storing computer-executable code that, when executed by a processor, causes the processor to:
receive a request to execute a vehicle platooning maneuver from a vehicle operating in a roadway environment;
execute a simulation that is seeded with hierarchical artificial intelligence (AI) data;
determine an area in the roadway environment where the vehicle platooning maneuver is executed based on the simulation; and
instruct the vehicle to execute the vehicle platooning maneuver at the area.

2. The computer program product of claim 1, wherein the hierarchical AI data describes one or more of the following: real-life traffic information; real-time traffic information; and predicted future traffic information.

3. The computer program product of claim 1, wherein the computer-executable code, when executed by the processor, causes the processor further to:
determine whether to reconfigure a vehicle platoon after the vehicle platooning maneuver is executed so that one or more goals are satisfied.

4. The computer program product of claim 1, wherein the computer-executable code, when executed by the processor, causes the processor further to:
determine how to reconfigure a vehicle platoon after the vehicle platooning maneuver is executed so that one or more goals are satisfied.

5. A method comprising:
receiving a request to execute a vehicle platooning maneuver from a vehicle operating in a roadway environment;
executing a simulation;
determining an area in the roadway environment where the vehicle platooning maneuver is executed based on the simulation; and
instructing the vehicle to execute the vehicle platooning maneuver at the area.

6. The method of claim 5, wherein the vehicle is an autonomous vehicle.

7. The method of claim 5, wherein the simulation is a digital twin simulation.

8. The method of claim 5, wherein the simulation is seeded with hierarchical artificial intelligence data that describes one or more of the following: real-life traffic information; real-time traffic information; and predicted future traffic information.

9. The method of claim 5, wherein the method is executed by at least one processor-based computing device selected from the following set of processor-based computing devices: an onboard unit of a leader vehicle of a vehicle platoon; and a server.

10. The method of claim 5, further comprising:
determining whether to reconfigure a vehicle platoon after the vehicle platooning maneuver is executed so that one or more goals are satisfied.

11. The method of claim 5, further comprising:
determining how to reconfigure a vehicle platoon after the vehicle platooning maneuver is executed so that one or more goals are satisfied.

12. The method of claim 5, wherein executing the simulation comprises:
determining a set of candidate areas in the roadway environment for executing the vehicle platooning maneuver;
executing the simulation to implement the vehicle platooning maneuver at the set of candidate areas respectively; and
selecting, from the set of candidate areas, a candidate area where an execution of the vehicle platooning maneuver in the simulation satisfies one or more platooning requirements,
wherein the candidate area is determined as the area in the roadway environment where the vehicle platooning maneuver is executed.

13. A system comprising:
a computer system including a non-transitory memory storing computer code which, when executed by the computer system, causes the computer system to:
receive a request to execute a vehicle platooning maneuver from a vehicle operating in a roadway environment;
execute a simulation;
determine an area in the roadway environment where the vehicle platooning maneuver is executed based on the simulation; and
instruct the vehicle to execute the vehicle platooning maneuver at the area.

14. The system of claim 13, wherein the vehicle is an autonomous vehicle.

15. The system of claim 13, wherein the simulation is a digital twin simulation.

16. The system of claim 13, wherein the simulation is seeded with hierarchical artificial intelligence data that describes one or more of the following: real-life traffic information; real-time traffic information; and predicted future traffic information.

17. The system of claim 13, wherein the computer system is included in at least one processor-based computing device selected from the following set of processor-based computing devices: an onboard unit of a leader vehicle of a vehicle platoon; and a server.

18. The system of claim 13, wherein the computer code, when executed by the computer system, causes the computer system further to:
determine whether to reconfigure a vehicle platoon after the vehicle platooning maneuver is executed so that one or more goals are satisfied.

19. The system of claim 13, wherein the computer code, when executed by the computer system, causes the computer system further to:
determine how to reconfigure a vehicle platoon after the vehicle platooning maneuver is executed so that one or more goals are satisfied.

20. The system of claim 13, wherein the computer code, when executed by the computer system, causes the computer system to execute the simulation at least by:
determining a set of candidate areas in the roadway environment for executing the vehicle platooning maneuver;
executing the simulation to implement the vehicle platooning maneuver at the set of candidate areas respectively; and
selecting, from the set of candidate areas, a candidate area where an execution of the vehicle platooning maneuver in the simulation satisfies one or more platooning requirements,
wherein the candidate area is determined as the area in the roadway environment where the vehicle platooning maneuver is executed.
